(19) United States
(12) Patent Application Publication
(10) Pub. No.: US 2007/0063338 A1
(43) Pub. Date: Mar. 22, 2007

(54) Bottom lighting type backlight module

(75) Inventors: Shao-Han Chang, Tu-cheng (TW); Fen Chen, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/499,320

(22) Filed: Aug. 4, 2006

(30) Foreign Application Priority Data
Sep. 16, 2005 (CN) 200510037356.3

(51) Int. Cl. H01L 23/34

(52) U.S. Cl. 257/714

(57) ABSTRACT

A bottom lighting type backlight module includes a frame, a light diffusion plate and a plurality of light sources. The frame includes a base and a plurality of sidewalls extending from the peripheral of the base to define an opening. The base defines a plurality of heat dissipation channels therein. The heat dissipation channels are filled with a cooling liquid. The light diffusion plate disposed on the opening of the frame. The light sources are arranged on the base of the frame. The present backlight module has a thin body with good heat dissipation capability.

### 1. TECHNICAL FIELD

The present invention relates to backlight module, more particularly, to a bottom lighting type backlight module for use in, for example, a liquid crystal display (LCD) device.

### 2. BACKGROUND

Most LCD devices are passive devices in which images are displayed by controlling an amount of light input from an outside light source. Thus, a separate light source (for example, backlight module) is generally employed for illuminating an LCD.

Generally, backlight module can be classified into an edge lighting type or a bottom lighting type based upon the location of lamps within the device. The edge lighting type backlight module has a lamp unit arranged at a side portion of a light guiding plate for guiding light. The edge lighting type backlight modules are commonly employed in small-sized LCD due to their lightweight, small size, and low electric consumption. However, the edge lighting type backlight modules are not suitable for large-sized LCD (20 inches or more). A bottom lighting type backlight module has a plurality of lamps arranged in regular positions to directly illuminate an entire surface of an LCD panel. The bottom lighting type backlight modules have higher efficiency of light usage and longer operational lifetime than the edge lighting type backlight modules, the bottom lighting type backlight modules are especially used in large-sized LCD devices. However, an LCD device usually employs a significant amount of lamps to reach a high luminance. The significant amount of lamps results in a great deal of heat produced and cumulated inside the LCD device. Therefore, heat dissipation of the direct type backlight modules is usually a hard nut to crack.

Referring to FIG. 2, a typical bottom-lighting backlight module 30 is shown. The backlight module 30 includes a frame 31, a heat dissipation panel 32, a plurality of optical sheets 33, a plurality of light emitting diodes 34 and a reflecting unit 35. The frame 31 is a rectangular-shaped housing having four connecting sidewalls (not labeled). The heat dissipation panel 32 is mounted into a bottom of the sidewalls of the frame 31. Accordingly, the heat dissipation panel 32 and the frame 31 collectively define a chamber (not labeled) thereby. The heat dissipation panel 32 includes a rectangular base 321 shaped corresponding to the frame 31 and a plurality of fins 322 extending out from a bottom surface of the base 321 perpendicularly.

The optical sheets 33 are layered on a top of the sidewalls of the frame 31 facing the base 321. The light emitting diodes 34 are aligned on an upper surface of the base of the heat dissipation panel 32 facing the optical sheets 33. The reflecting unit 35 defines a plurality of holes (not labeled) therein according to the light emitting diodes 34. The reflecting unit 35 is disposed on the base 321 of the heat dissipation panel 32. The reflecting unit 35 further defines a plurality of holes exposing the light emitting diodes 34 to emit light rays to enter the optical sheets 33 through the holes thereof. The base 321 of the heat dissipation panel 32 is usually formed of materials with a high heat conductive coefficient. This is because the base 321 is in direct contact with the light emitting diodes 34, a great deal of heat produced by the light emitting diodes 34 can be directly dissipated out through the base 321 and the fins 322.

As described the components of the backlight module 30 are plentiful, thus assembling the backlight module is complicated and difficult. In addition, the thickness of the backlight module 30 is limited due to the physical properties of the heat dissipation panel 32. Furthermore, the heat dissipation panel 32 commonly needs an auxiliary device such as a fan, to increase its heat dissipation efficiency. If, however, an air-cooling fan is used, dust is whirled up to adhere to the surface of light emitting diodes 33 or to the optical sheets 33 disposed thereon, thus deteriorating the uniformity of brightness of the backlight module 30. Furthermore, a noise produced by the fan is also a shortcoming.

What is needed, therefore, is a bottom lighting type backlight module that overcome the above mentioned shortcomings.

### SUMMARY

A bottom lighting type backlight module according to a preferred embodiment includes a frame, a light diffusion plate and a plurality of light sources. The frame includes a base and a plurality of sidewalls extending from the peripheral of the base to define an opening. The base defines a plurality of heat dissipation channels therein. The heat dissipation channels are filled with a cooling liquid. The light diffusion plate is disposed on the opening of the frame. The light sources are arranged on the base of the frame.

Other advantages and novel features will become more apparent from the following detailed description of the preferred embodiments, when taken in conjunction with the accompanying drawings.

### BRIEF DESCRIPTION OF THE DRAWINGS

Many aspects of the present bottom lighting type backlight module can be better understood with reference to the following drawings. The components in the drawings are not necessarily drawn to scale, the emphasis instead being placed upon clearly illustrating the principles of the present bottom lighting type backlight module. Moreover, in the drawings, like reference numerals designate corresponding parts throughout the several views.

FIG. 1 is a schematic, cross-sectional view of the bottom lighting type backlight module according to a preferred embodiment; and

FIG. 2 is a schematic, cross-sectional view of a conventional bottom lighting type backlight module.

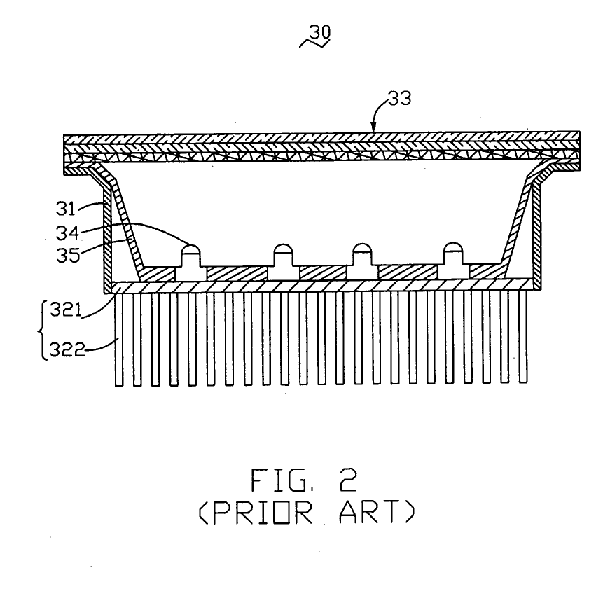

### DETAILED DESCRIPTION OF THE PREFERRED EMBODIMENTS

Reference will now be made to the drawings to describe preferred embodiments of the present bottom lighting type backlight module, in detail.

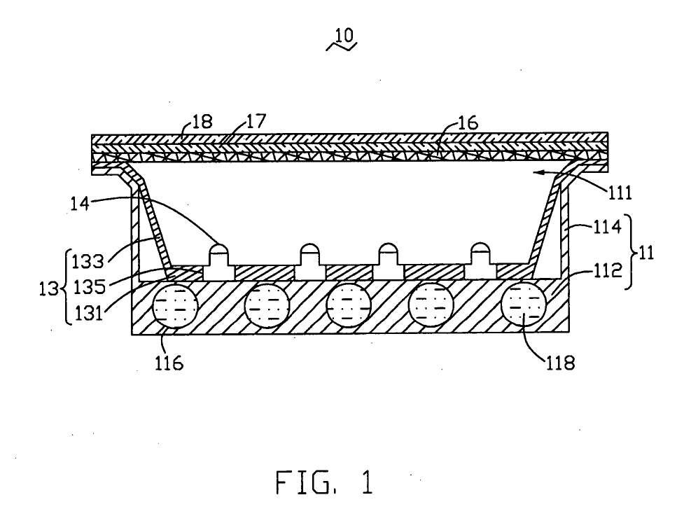

Referring to FIG. 1, a bottom lighting type backlight module 10 in accordance with a preferred embodiment is shown. The backlight module 10 includes a frame 11, a plurality of light emitting diodes 14, and a light diffusion plate 16. The frame 11 is a rectangular-shaped housing, which includes a base 112 and a plurality of sidewalls 114 extending from the peripheral of the base 112 to define an opening 111. The base 112 defines a plurality of heat dissipation channels 116 therein. The heat dissipation channels 116 are filled with a cooling liquid 118. The light emitting diodes 14 are arranged on the base 112 of the frame 11 in a matrix manner. The light diffusion plate 16 is disposed on the opening 111 of the frame 11.

In order to define the heat dissipation channels 116 in the base 112 of the frame 11, a thickness of the base 112 is configured to be larger than that of the sidewalls 114. The frame 11 may be integrally manufactured by pressing method. The plurality of heat dissipation channels 116 are connected with each other and distributed in the base 112 substantially. This allows heat to be absorbed by the cooling liquid 118 efficiently. The heat dissipation channels 116 may be connected to an external cooling liquid source (not shown) to form a liquid cooling system (not shown). In this embodiment, a distribution of the heat dissipation channels 116 forms a plurality of connecting “S” shapes. The frame 11 is formed of materials with a high heat conductive coefficient, such as copper, aluminum, or other suitable materials.

In order to improve the backlight module 10's light energy utilization rate, the backlight module may further include a reflecting unit 13. The reflecting unit 13 includes a substrate 131 and a plurality of reflecting sidewalls 133 extending from the peripheral of the substrate 131. Atop end of the reflecting sidewalls 133 is in contact with a top of the sidewalls 114 of the frame 11 correspondingly. The substrate 131 defines a plurality of holes 135 therein arranged corresponding to an arrangement of the light emitting diodes 14. The reflecting unit 13 is disposed on the base 112 of the frame 11 such that the light emitting diodes protrudes through the holes 135 to emit light rays to enter the light diffusion plate 16.

The backlight module 10 may further include a thermal interface material (TIM) (not shown) applied between the light emitting diodes 14 and the base 112, so as to improve a thermal conductive rate.

In order to improve the backlight module 10's optical brightness, the backlight module 10 may further include a prism sheet 17 and a brightness enhancement sheet 18 stacked on the light diffusion plate 16 in that order.

In use, light rays emitted by the light emitting diodes 14 are directly emitted into the light diffusion plate 12, and a substantial remainder of the light rays emitted from the light emitting diodes 14 that does not directly emit into the light diffusion plate are reflected to the light diffusion plate 16 by the reflecting unit 13. Some of the light rays are reflected by an incident surface of the light diffusion plate 16, and these are reflected back to the light diffusion plate 16 by the reflecting unit 13. The light rays are diffused in the light diffusion plate 16, and thus surface light rays are output from a LCD panel (not shown) stacked on the light diffusion plate 16.

Heat produced by the light emitting diodes 14 can be conducted to the base 112 and dispersed by the cooling liquid 118 flowing in the heat dissipation channels 116. Thus, a temperature of the backlight module 10 can be maintained at a normal level to prolong the working lifetime of it. Furthermore the present backlight module 10 has a thin body and can dissipate heat efficiently without the help of a fan.

Finally, while the present invention has been described with reference to particular embodiments, the description is illustrative of the invention and is not to be construed as limiting the invention. Therefore, various modifications can be made to the embodiments by those skilled in the art without departing from the true spirit and scope of the invention as defined by the appended claims.

What is claimed is:

1. A bottom lighting type backlight module comprising:
a frame having a base and a plurality of sidewalls extending from the peripheral of the base to define an opening, wherein the base defines a plurality of heat dissipation channels therein, and the heat dissipation channels are filled with a cooling liquid;
a light diffusion plate disposed on the opening of the frame; and
a plurality of light sources arranged on the base of the frame.

2. The bottom lighting type backlight module according to claim 1, wherein the light sources are light emitting diodes.

3. The bottom lighting type backlight module according to claim 2, wherein the light emitting diodes are arranged on the base of the frame in a matrix manner.

4. The bottom lighting type backlight module according to claim 1, further comprising a reflecting unit having a substrate and a plurality of reflecting sidewalls extending from the peripheral of the substrate, wherein the substrate defines a plurality of holes therein according to the light sources, the reflecting unit is disposed on the base of the frame such that the light emitting diodes protrudes through the holes to emit light rays to enter the light diffusion plate.

5. The bottom lighting type backlight module according to claim 1, further comprising a prism sheet disposed on the light diffusion plate.

6. The bottom lighting type backlight module according to claim 5, further comprising a brightness enhancement sheet disposed on the prism sheet.

7. The bottom lighting type backlight module according to claim 1, wherein a material of the frame is selected from a group comprising copper and aluminum.

8. The bottom lighting type backlight module according to claim 1, wherein the heat dissipation channels are connected with each other and distributed in the base substantially, so as to absorb heat to the cooling liquid efficiently.

9. A backlight module comprising:
a plurality of light sources;
a light diffusion member arranged to receive light emitted from the light source;
a frame including a base thermally contacting the light sources, the base defining a plurality of heat dissipation channels therein;
a cooling fluid contained in the heat dissipation channels, wherein when the light sources emit light, the heat generated thereby is conducted to the base and then to the cooling fluid.
